(19) United States
(12) Patent Application Publication
(10) Pub. No.: US 2024/0331179 A1
(43) Pub. Date: Oct. 3, 2024

(54) 3D VOLUME INSPECTION OF SEMICONDUCTOR WAFERS WITH INCREASED ACCURACY

(71) Applicant: Carl Zeiss SMT GmbH, Oberkochen (DE)

(72) Inventors: Dmitry Klochkov, Schwäbisch Gmünd (DE); Eugen Foca, Ellwangen (DE); Jens Timo Neumann, Aalen (DE); Thomas Korb, Schwäbisch Gmünd (DE); Alex Buxbaum, San Ramon, CA (US); Amir Avishai, Pleasanton, CA (US); Chuong Huynh, Quincy, MA (US)

(21) Appl. No.: 18/736,705

(22) Filed: Jun. 7, 2024

Related U.S. Application Data
(63) Continuation of application No. PCT/EP2022/082804, filed on Nov. 22, 2022.
(60) Provisional application No. 63/292,043, filed on Dec. 21, 2021.

(51) Int. Cl. G06T 7/55; G01N 1/28; G01N 23/203; G01N 23/2206; G06T 7/00; G06T 7/521

(52) U.S. Cl. CPC G06T 7/55; G01N 1/286; G01N 23/203; G01N 23/2206; G06T 7/0004; G06T 7/521; G01N 2001/2873; G01N 2223/401; G01N 2223/6116; G06T 2200/04; G06T 2207/10056; G06T 2207/30148

(57) ABSTRACT

A system and a method for volume inspection of semiconductor wafers are configured for milling and imaging of reduced number or areas of appropriate cross-sections surfaces in an inspection volume and determining inspection parameters of the 3D objects from the cross-section surface images. The system and method can be utilized for quantitative metrology, defect detection, process monitoring, defect review, and inspection of integrated circuits within semiconductor wafers.

### CROSS REFERENCE TO RELATED APPLICATIONS

The present application is a continuation of, and claims benefit under 35 USC 120 to, international application No. PCT/EP2022/082804, filed Nov. 22, 2022, which claims benefit under 35 USC § 119 (e) of U.S. Provisional Application No. 63/292,043, filed Dec. 21, 2021. The entire disclosure of each of these applications is incorporated by reference herein.

### FIELD

The present disclosure relates to a three-dimensional circuit pattern inspection method, computer program product and a corresponding semiconductor inspection device of an inspection volume at an inspection site of a semiconductor wafer. The present disclosure relates to a method, computer program product and a corresponding semiconductor inspection device for determining parameters of 3D objects such as HAR structures in the inspection volume of a semiconductor wafer with increased precision and accuracy. The method can employ milling and imaging of a plurality of cross-sections surfaces in an inspection volume and determining inspection parameters of the 3D objects from the cross-section surface images with relatively high accuracy and relatively high robustness. A method, computer program product and device can be used for quantitative metrology, defect detection, process monitoring, defect review, and/or inspection of integrated circuits within semiconductor wafers.

### BACKGROUND

Semiconductor structures are amongst the finest man-made structures and suffer from only very few imperfections. These rare imperfections are the signatures which defect detection or defect review or quantitative metrology devices are looking for. Fabricated semiconductor structures are often based on prior knowledge, for example from design data and fabricated from a limited number of materials and processes. Furthermore, the semiconductor structures are generally manufactured in a sequence of layers being parallel to the surface of a silicon wafer substrate. For example, in a logic type sample, metal lines are running parallel in metal layers and HAR (high aspect ratio) structures and vias can run perpendicular to the metal layers. The angle between metal lines in different layers is commonly either 0° or 90°. On the other hand, for VNAND type structures it is known that their cross-sections can be circular on average and arranged in a regular raster perpendicular to the surface of a silicon wafer. During manufacturing, a huge number of three-dimensional semiconductor structures is typically generated in a wafer, wherein the fabrication process is subject to several influences. Generally, the edge shapes, areas or overlay positions of semiconductor structures may be subject to the property of involved materials, the lithography exposure, or any other involved manufacturing step, such as etching, polishing, deposition, or implantation.

In the fabrication of integrated circuits, the features size is becoming smaller. The current minimum feature size or critical dimension is below 10 nanometers (nm), for example 7 nm or 5 nm, and approaching below 3 nm in near future. Therefore, measuring edge shapes of patterns, and to determine the dimensions of structures or the line edge roughness with high precision can become challenging. The measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can be reduced with no physical limitation. The charged particle beam diameter generally has a limited dimension, which depends on the selected type of charged particle, the charged particle beam operation conditions and charged particle lens system utilized. The beam resolution is generally limited by approximately half of the beam diameter. The resolution can be below 3 nm, for example below 2 nm, or even below 1 nm.

With the features sizes of integrated semiconductor circuits becoming smaller, and with the increasing desired resolution of charged particle imaging systems, the inspection and 3D analysis of three-dimensional integrated semiconductor structures in wafers can become more and more challenging. A semiconductor wafer has a diameter of 300 mm and includes a plurality of several sites, so called dies, each comprising at least one integrated circuit pattern such as for example for a memory chip or for a processor chip. Semiconductor wafers typically run through about 1000 process steps, and within the semiconductor wafer, about 100 and more parallel layers are formed, comprising the transistor layers, the layers of the middle of the line, and the interconnect layers and, in memory devices, a plurality of 3D arrays of memory cells.

A common way to generate 3D tomographic data from semiconductor samples on nm scale is the so-called slice and image approach performed for example by a dual beam device. A slice and image approach is described in WO 2020/244795 A1. According to the method of the WO 2020/244795 A1, a 3D volume inspection is obtained at an inspection sample extracted from a semiconductor wafer. In this method, a wafer is destroyed to obtain an inspection sample. This can be addressed by utilizing the slice and image method under a slanted angle into the surface of a semiconductor wafer, as described in WO 2021/180600 A1. According to this method, at least a first inspection site is determined, and 3D volume image of an inspection volume is obtained by slicing and imaging a plurality of cross-section surfaces of the inspection volume. In a first example for a precise measurement, a large number N of cross-section surfaces of the inspection volume is generated, with the number N exceeding 100 or even more image slices. For example, in a volume with a lateral dimension of 5 μm and a slicing distance of 5 nm, 1000 slices are milled and imaged. For the alignment and registration of the cross-section image slices, a plurality of different methods has been proposed. For example, reference marks or so-called fiducials can be employed, or a feature-based alignment can be employed. However, according to recent desired properties and in many application examples, these methods turned out to leave wanting further improvements of the alignment and registration of the plurality of cross-section images slices.

According to several inspection tasks, a full 3D volume image with higher accuracy is used. In some application examples, certain semiconductor features offer a low imaging contrast and a proper computation of a depth map or an alignment via such features is not possible. In an example, the task of the inspection is to determine a set of specific parameters of semiconductor objects such as high aspect ratio (HAR)—structures inside the inspection volume with high precision. In some cases, however, methods described in WO 2021/180600 A1 may not provide sufficient information for the determination of a set of parameters of complex semiconductor structures. It has also been observed that in some examples the methods according to WO 2021/180600 A1 can generate measurement artefacts.

### SUMMARY

The disclosure seeks to provide improved methods. The disclosure seeks to provide a wafer inspection method for the inspection of three-dimensional semiconductor structures in inspection volumes with higher accuracy and higher robustness. The disclosure seeks to provide a relatively fast and relatively reliable measurement method of a set of parameters describing three-dimensional semiconductor structures in an inspection volume with relatively high precision even if the depth map generation according second semiconductor structures of know depth are not present or only hardly detectable.

The disclosure provides a system and method configured for milling and imaging of a plurality of cross-sections surfaces in an inspection volume and determining inspection parameters of the 3D objects from the plurality of cross-section surface images. The disclosure provides a device and a method for 3D inspection of an inspection volume in a wafer and for the determination of a set of parameters of semiconductor features inside of the inspection volume with high accuracy and robustness. The disclosure provides a method and device that can be utilized for quantitative metrology, defect detection, process monitoring, defect review, and inspection of integrated circuits within semiconductor wafers.

According to an aspect of the disclosure, a method for generating a 3D volume image of an inspection volume in a semiconductor wafer is provided. The method comprises a first step of obtaining a plurality of J cross section image slices by iteratively and subsequently milling and imaging a plurality of cross-section surfaces at a slanted angle GF through the inspection volume. The number J of cross section image slices can be greater than 200, greater than 1000, or greater than 5000. The method further comprises the step of determining a set of N measured cross-section values u1 . . . uN of a group of structures of presumably known depth from the plurality of J cross section image slices. The structures of presumably known depth are for example word lines of connections in selected layers of known depth in the semiconductor wafer. The method comprises a further step of determining, from the set of N measured cross section values u1 . . . uN, a set of W modelled cross-section values v1 . . . vW of the group of structures of presumably known depth.

From the set of W modelled cross-section values v1 . . . vW, a depth map Zj(x,y) is computed for each of the cross section image slices. A 3D volume image is determined from the plurality of J cross section image slices and the plurality of depth maps Zj(x,y). With the set of W modelled cross-section values, a measurement error or a determination error of the measured cross-section values can be minimized and a computation of the depth maps can be more robust against errors. Furthermore, with the set of W modelled cross-section values, missing depth information from for example low contrast cross section images of the structures of presumably known depth can be interpolated and the depth maps can be determined even with relatively sparse measurement information.

In an example, each of the cross-section values represent an edge position or a center position of one of the structures of presumably known depth. The set of W modelled cross-section values v1 . . . vW can by described by a parameter model having a number of R<N parameters, and the R parameters of the set of W modelled cross-section values v1 . . . vW can be determined from the set of measured cross-section values v1 . . . vN by least square optimization. The parameter model can be selected according to a-priori information, for example by consideration of expected imaging and milling errors, or by consideration of the expected position of the layers in a semiconductor wafer. In an example, the set of W modelled cross-section values v1 . . . vW is described by the addition of a first parameter model S representing a shift error of the lateral positions of the cross-section values of the group of structures of presumably known depth in each of the image slices. The description can further comprise a second parameter model T according to a local error of the milling angle GF of a cross section surface.

In an example, the method further comprises the steps of determining at least a second set of measured cross section values of a group of repetitive three-dimensional structures in the plurality of J cross section image slices, and the step of determining a property of the group of repetitive three-dimensional structures. With the relatively robust determination of the depth maps, property of the group of repetitive three-dimensional structures of interest can be determined with higher accuracy and higher robustness. The second set of measured cross section values can for example represent center positions of cross sections of the group of repetitive three-dimensional structures.

According to an embodiment, a method is provided, according to which a plurality of lateral displacements of the center positions of cross sections of the group of repetitive three-dimensional structures from reference center positions are determined. From the lateral displacements, an average lateral displacement of the center positions is obtained for each cross-section image slice. With the average displacement, the lateral positioning alignment of a plurality of cross section image slices can be improved. Therefore, a high frequency part of the average displacement from cross section image slice to cross section image slice can be filtered out, such that the slowly varying trajectories of repetitive three-dimensional structures are maintained. The trajectories of repetitive three-dimensional structures can thus be measured with higher accuracy.

According to an aspect of the disclosure, an inspection system for generating a 3D volume image of an inspection volume in a semiconductor wafer is provided. The inspection system comprises a wafer support on a wafer stage for receiving a wafer and a dual beam system. The dual beam system comprises a focused ion beam (FIB) arranged at a slanted angle GF with respect a surface of the wafer support and an imaging charged particle beam system arranged at an angle approximately perpendicular to the surface of the wafer support. A control unit with a memory and a processor is configured for executing during use instructions to perform any of the method steps described above. In an example, the inspection system further comprises a precision interferometer for controlling a position of the wafer stage, and a housing for controlling a vacuum condition within the housing, wherein the precision interferometer and the wafer stage are within the housing. Thereby, a 3D volume can be obtained with even higher precision.

The disclosure described by examples and embodiments is not limited to the embodiments and examples but can be implemented by those skilled in the art by various combinations or modifications.

### BRIEF DESCRIPTION OF THE DRAWINGS

The present disclosure will be even more fully understood with reference to the following drawings:

FIG. 1 is an illustration of a wafer inspection system for 3D volume inspection with a dual beam device;

FIG. 2 is an illustration of a method of volume inspection in a wafer with a slanted cross-section milling and imaging by the dial beam device;

FIG. 3 illustrates two examples of cross-section images slices;

FIG. 4 is a flow chart of a method according to the second embodiment;

FIG. 5 is an illustration of a plurality of cross sections of a plurality of cross-section surfaces with layers of known depth;

FIG. 6 is an illustration example of a cross-section image slice;

FIG. 7 is an illustration of an example of the cross sections with layers of known depth in a cross-section image slice;

FIG. 8 is an illustration of a parameterized model of cross sections with layers of known depth in a cross-section image slice according to the second embodiment;

FIG. 9 is an illustration of a plurality of cross sections of a plurality of cross-section surfaces with a plurality of HAR structures;

FIGS. 10A-10B illustrate of a data stack of cross-section image slices with initial alignment;

FIG. 11 is a flow chart of method steps in the third embodiment;

FIG. 12 is an illustration of a data stack of cross-section image slices after low pass filtering; and

FIGS. 13A-13D illustrate of the extraction and determination of parameters of the HAR structures.

### DETAILED DESCRIPTION

Throughout the figures and the description, same reference numbers are used to describe same or similar features or components. The coordinate system is selected that the wafer surface 55 coincides with the XY-plane.

Recently, for the investigation of 3D inspection volumes in semiconductor wafers, a slice and imaging method has been proposed, which is applicable to inspection volumes inside a wafer. Thereby, a 3D volume image is generated at an inspection volume inside a wafer in the so called “wedge-cut” approach or wedge-cut geometry, without the need of a removal of a sample from the wafer. The slice- and image method is applied to an inspection volume with dimensions of few μm, for example with a lateral extension of 5 μm to 10 μm or up to 50 μm in wafers with diameters of 200 mm or 300 mm. A V-shaped groove or edge is milled in the top surface of an integrated semiconductor wafer to make accessible a cross-section surface at a slanted angle to the top surface. 3D volume images of inspection volumes are acquired at a limited number of measurement sites, for example representative sites of dies, for example at process control monitors (PCM), or at sites identified by other inspection tools. The slice and image method will destroy the wafer only locally, and other dies may still be used, or the wafer may still be used for further processing. The methods and inspection systems according to the 3D Volume image generation are described in WO 2021/180600 A1, which is fully incorporated herein by reference. The current disclosure seeks to provide an improvement and extension to the methods and inspection systems according to the 3D Volume image generation, where a higher accuracy is involved. The present disclosure seeks to provide an improved method with a unified computational algorithm.

One of the challenges of the slice-and-imaging approach for semiconductor devices is the 3D volume data generation out of the plurality of cross-section image slices. To obtain a high precision or accuracy, each slice not only has to be aligned with respect to a lateral position with respect to a reference position in x- and y-coordinates, but for each slice a depth map Zᵢ(x,y) has to be derived. Furthermore, each slice can show a distortion according to a milling or imaging condition of the slanted cross-section surface in the wafer.

The proposed disclosure is specifically focused on the semiconductor devices consisting of semiconductor-elements with high aspect ratio and/or located in multiple layers inside the device. Manufacturing of such devices strongly relies on the ability to characterize the semiconductor-elements in 3D. The full-scale 3D tomography according to the method and apparatus of the disclosure can provide an improved slice-and-imaging technique and provides the most complete information about the investigated volume of a semiconductor wafer.

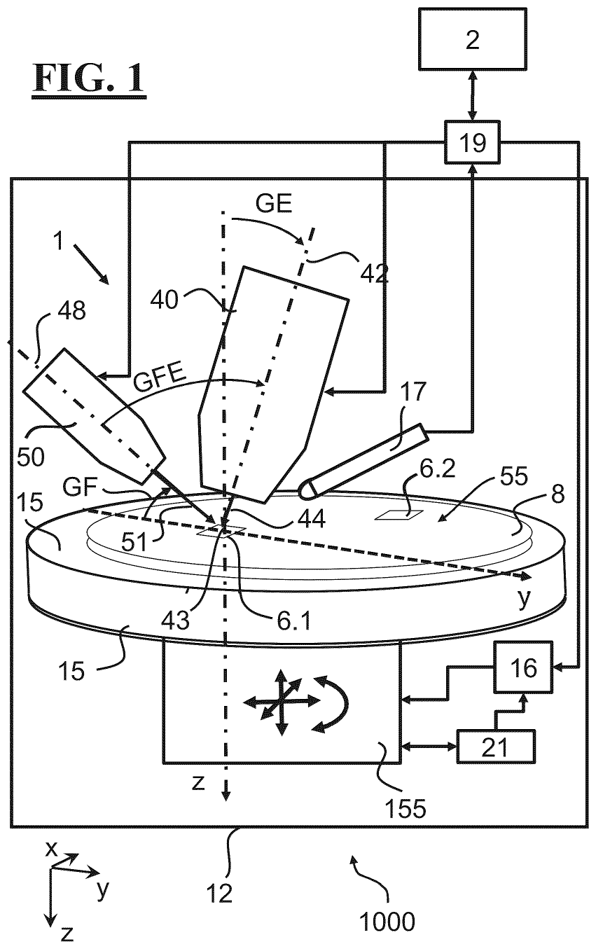

A first embodiment of the disclosure is illustrated in FIG. 1. According to the first embodiment, a wafer inspection system 1000 for 3D volume inspection is provided. The wafer inspection system 1000 for 3D volume inspection is configured for a slice and imaging method under wedge cut geometry with a dual beam device 1. For a wafer 8, several measurement sites, comprising measurement sites 6.1 and 6.2, are defined in a location map or inspection list generated from an inspection tool or from design information. The wafer 8 is placed on a wafer support table 15. The wafer support table 15 is mounted on a stage 155 with actuators and position control 21. Actuators and mechanisms for precision control 21 for a wafer stage 155 such as Laser interferometers are known in the art. A control unit 16 receives information about the actual position of the wafer stage 155 and is configured to control the wafer stage 155 and to adjust a measurement site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. At the intersection point 43 of both optical axes of FIB and CPB imaging system, the wafer surface 55 is arranged at a slant angle GF to the FIB axis 48. FIB axis 48 and CPB imaging system axis 42 include an angle GFE, and the CPB imaging system axis forms an angle GE with normal to the wafer surface 55. In the coordinate system of FIG. 1, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF at a predetermined y-position, which is controlled by the stage 155 and position control 21. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam, or due to variable material properties with respect to milling along the cross-section surface. With the charged particle beam imaging system 40, inclined under angle GE to the wafer normal, images of the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer at measurement site 6.1, and secondary particles as well as backscattered particles are generated. Particle detector 17 collects at least some of the secondary particles and/or backscattered particles and communicates the particle count with a control unit 19. Other detectors for other kinds of interaction products such as x-rays or photons may be present as well. Control unit 19 is in control of the charged particle beam imaging column 40, of the FIB column 50 and connected to a control unit 16 to control the position of the wafer mounted on the wafer support table 15 via the wafer stage 155.

Operation control unit 2 communicates with control unit 19, which triggers placement and alignment for example of measurement site 6.1 of the wafer 8 at the intersection point 43 via wafer stage movement and triggers repeatedly operations of FIB milling, image acquisition and stage movements. Control unit 19 and Operation control unit 2 comprises a memory for storing instructions in form of software code and at least one processer to execute during operation the instructions, for example to execute the methods described in the second and third embodiment. A memory is further provided to store digital image data. Operation control unit 2 may further comprise a user interface or an interface to other communication interfaces to receive instructions and to transfer inspection results.

Each new intersection surface is milled by the FIB beam 51, and imaged by the charged particle imaging beam 44, which is for example scanning electron beam or a Helium-Ion-beam of a Helium ion microscope (HIM).

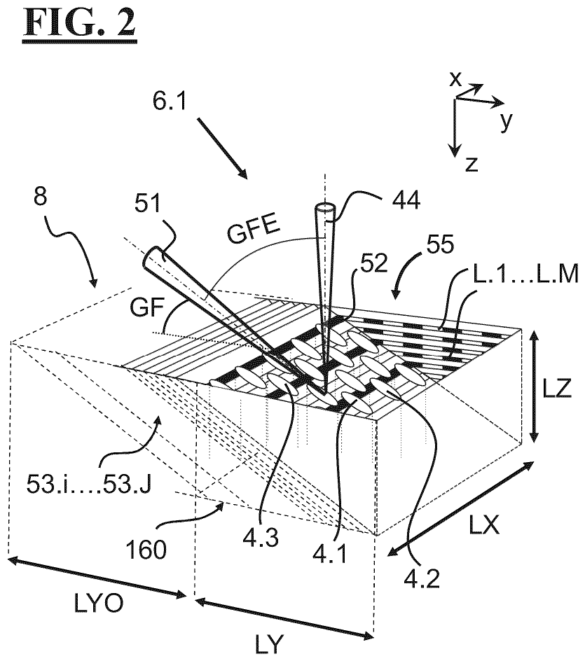

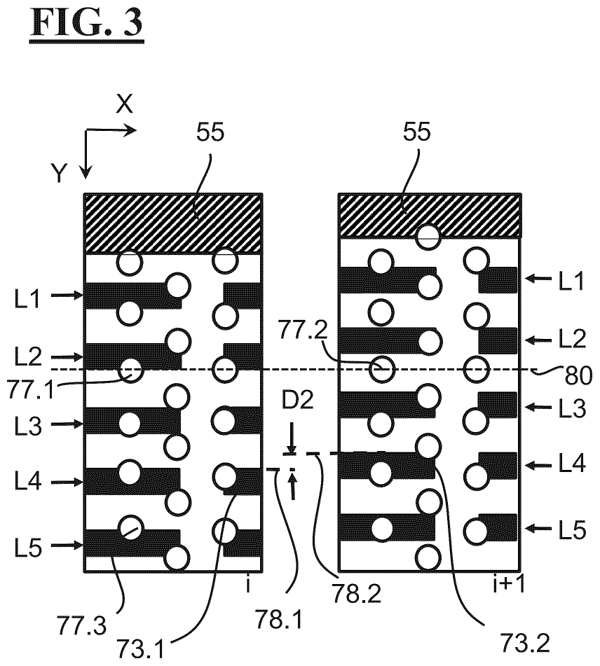

FIG. 2 illustrates certain details of the slice and imaging method in the wedge cut geometry. By repetition of the slicing and imaging method in wedge-cut geometry, a plurality of J cross-section image slices comprising image slices of cross-section surfaces 52, 53.i . . . 53.J is generated and a 3D volume image of an inspection volume 160 at an inspection site 6.1 of the wafer 8 at measurement site 6.1 is generated. FIG. 2 illustrates the wedge cut geometry at the example of a 3D-memory stack. The cross-section surfaces 53.1 . . . 53.J are milled with a FIB beam 51 at an angle GF of approximately 30° to the wafer surface 9, but other angles GF, for example between GF=20° and GF=60° are possible as well. FIG. 2 illustrates the situation, when the surface 52 is the new cross-section surface which was milled last by FIB 51. The cross-section surface 52 is scanned for example by SEM beam 44, which is in the example of FIG. 2 arranged at normal incidence to the wafer surface 55, and a high-resolution cross-section image slice is generated. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN— or Tungsten lines. Some of the lines are also called “word-lines”. The maximum number M of layers is typically more than 50, for example more than 100 or even more than 200. The HAR-structures and layers extend throughout most of the inspection volume in the wafer but may structures or layers may comprise gaps. The HAR structures typically have diameters below 100 nm, for example about 80 nm, or for example 40 nm. The HAR structures are arranged in a regular, for example hexagonal raster with a pitch of about below 300 nm, for example even below 250 nm. The cross-section image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44. FIG. 3 illustrates an ith and (i+1)-th cross-section image slice at an example. The vertical HAR structures appear in the cross-section image slices as first cross-section image features 77, for example first cross-section image features 77.1, 77.2 and 77.3. Since the imaging charged particle beam 44 is oriented parallel to the HAR structures, the first cross-section image features representing for example an ideal HAR structure would appear at same y-coordinates. For example, first cross-section image features 77.1 and 77.2 of an ideal HAR structure are centered at line 80 with identical Y-coordinate of the ith and (i+1)-th image slice. The cross-section image slices further comprise a plurality of second cross-section image features of a plurality of layers comprising for example layers L1 to L5, for example second cross-section image features 73.1 and 73.2 of layer L4. The layer structure appears as segments of stripes along X-direction in the cross-section image slices. The position of these second cross-section image features representing the plurality of layers, here shown layers L1 to L5, however, changes with each cross-section image slice with respect to the first cross-section image features. As the layers intersect the image planes at increasing depth, the position of the second cross-section image features changes from image slice i to image slice i+1 in a predefined manner. For example, the upper surface of layer L4, indicated by reference numbers 78.1, 78.2, are displaced by distance D2 in y-direction. From determining the positions of the second cross-section image features, for example 78.1 and 78.2, the depth map Zᵢ(x,y) of a cross-section image can be determined.

Due to the planar fabrication techniques involved in the fabrication of a wafer, layers as for example layers L1 to L5 are at constant depth over a larger area of a wafer. The depth maps of first cross-section image slices can at least be determined relative the depth of second cross-section images features in the M layers. Further details for the generation of the depth maps Zⱼ(x,y) for the cross-section image slices are described in WO 2021/180600 A1. By feature extraction of the second cross-section image features, such as edge detection or centroid computation and image analysis, and according to the assumption of the same or similar depth of the second cross-section image features, the determination of the lateral position as well as the relative depth of the first cross-section image features in slanted cross-section image slices is therefore possible. However, as will be described below in more details, in some cases there are no second cross-section images features present in the M layers, or they can not be detected in the plurality of cross-section image slices with sufficient accuracy.

A plurality of J cross-section image slices acquired in this manner covers an inspection volume of the wafer 8 at measurement site 6.1 and is used for forming of a 3D volume image of high 3D resolution below for example 10 nm, such as below 5 nm. The inspection volume 160 (see FIG. 2) typically has a lateral extension of LX=LY=5 μm to 15 μm in x-y plane, and a depth LZ of 2 μm to 15 μm below the wafer surface 55. However, the extensions can also be larger and reach for example 50 μm. The full 3D volume image generation according to WO 2021/180600 A1 typically involves milling cross-section surfaces into the surface 55 of the wafer 8 with a larger extension in y-direction as the extension LY. In this example, the additional area with extension LYO is destroyed by the milling of the cross-section surfaces 53.1 to 53.J. In a typical example, the extension LYO exceeds 20 μm.

The operation control unit 2 (see FIG. 1) is configured to perform a 3D inspection inside an inspection volume 160 in a wafer 8. The operation control unit 2 is further configured to reconstruct the properties of semiconductor structures of interest from the 3D volume image. In an example, features and 3D positions of the semiconductor structures of interest, for example the positions of the HAR structures, are detected by the image processing methods, for example from HAR centroids. A 3D volume image generation including image processing methods and feature based alignment is further described in WO 2020/244795 A1, which is hereby incorporated by reference.

According to the disclosure, the precision of the 3D volume image data set can be improved.

According to a first embodiment, the disclosure provides a system for volume inspection. The system for volume inspection relies on a position sensor 21, which is utilized as a monitoring system during the milling and imaging process. In prior art, typically position sensors of low accuracy are used and the imaging of fiducials is used for an alignment of the images obtained. Thereby a higher accuracy is achieved even if low-cost position sensors are used. However, in an example of the first embodiment, the high-resolution position sensor 21 is used instead. Such high-resolution position sensors 21 are in principle known, but involve certain measures to the system 1000, for example a precision control unit (not shown) of the vacuum conditions or temperature conditions inside the vacuum compartment or housing 12. According to the example, the stage position is not controlled with the higher accuracy of the position sensor 21. According to the example, the stage position is monitored during milling and imaging with high precision of below few nm, for example 2 nm, 1 nm or even less. Thereby additional information of the lateral and z-positions of cross-section surfaces is obtained. For example, lateral stage drifts, which lead to offset the positions of the structures from image slice to image slice, are monitored and can be considered in the 3D volume image generation. Uncertainties in the z-position from stage drifts or variations can be monitored as well and the actual positions and angles of the cross-section surfaces generated by the FIB can be obtained with higher precision.

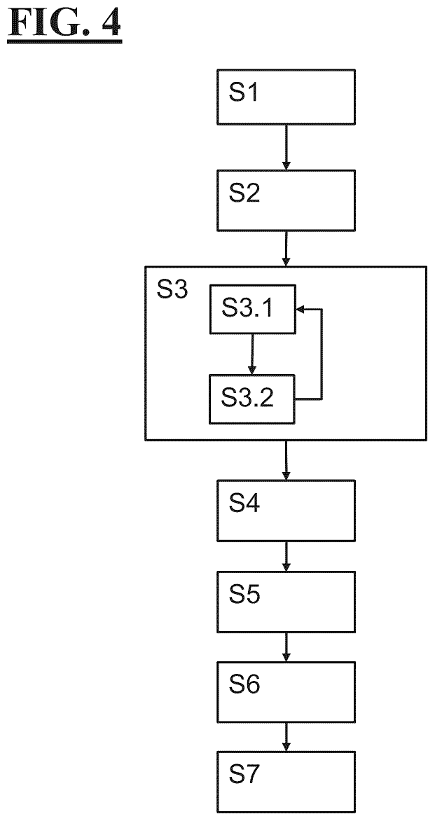

However, even with a high precision positions sensor 21, the position of the milling beam 43 and the imaging beam 44 can be deteriorated by system drifts or charging effects of the wafer, or by milling effects (for example curtaining effects). According to the second embodiment, an accurate and robust method of 3D inspection of a group of repetitive, three-dimensional structures in a wafer is given. The method is described in FIG. 4 according following steps.

In step S1, a wafer is loaded on the wafer support table 15 and the wafer coordinates are registered by methods known in the art. A wafer inspection file is loaded by the operation control unit 2 and at least a first inspection site 6.1 of an inspection task is determined. The first inspection site 6.1 at the wafer surface 15 is positioned under the intersection point 43 of the dual beam device 1.

In step S2, a dimension of the inspection volume 160 and a plurality of J cross-section surfaces through the inspection volume 160 is determined. For each cross-section surface, a y-coordinate and optionally a milling angle GF is determined. The plurality of J cross-section surfaces typically comprises cross-section surfaces at the same or similar angle GF and at equal distance d between 2 nm and 10 nm through the inspection volume. In an inspection volume of up to 10 μm, the number J can exceed more than 1000 image slices, for example J=5000 image or more slices.

Depending on the inspection task, further variables can be determined in step S2. For example, a specific parameter model for the group of repetitive, three-dimensional structures of interest can be determined. For example, the inspection task comprises the inspection of a first and a second group of repetitive, three-dimensional structures of interest.

Optionally, in step S2, alignment marks or fiducials are generated close to the inspection site 6.1 for repeated alignment of the inspection site 6.1.

In step S3, the slice and imaging process is performed and the plurality of J cross-section images slices from the plurality of cross section surfaces through the inspection volume 160 is obtained. In a first iterative step S3.1, a cross-section surface is milled by the FIB beam 51 at the predetermined y-position and the predetermined angle GF into the inspection volume 160. In a second iterative step S3.2 the new cross-section surface is imaged by the imaging charged particle beam 44 and a cross-section image slice is obtained and stored in the memory of the control unit 2. Steps 3.1 and 3.2 are repeated until the predetermined series of J cross-section images slices is completed. During both steps, the position of the wafer 8 with respect to the dual beam system 1 is monitored by the position sensor 21 and the actual sensor information is stored together with each of the cross-section image slices.

In step S4, a set of N measured cross-section values u1 . . . uN of a group of structures of presumably known depth is determined. During this determination, cross-section image segments of the structures of presumably known depth are detected in the series of J cross-section image slices by methods know in the art, and the cross-section values v1 . . . vN are determined. A cross-section value vi can be an edge position or a center position.

In step S5, a set of W modelled cross-section values v1 . . . vW of the group of structures of presumably known depth is derived. In an example, the number W is larger than the number N of measured cross sections values and missing measurements are interpolated. In an example, the number W is identical to N or even smaller, and measurement inaccuracies are compensated for by averaging, interpolation or filtering. Generally, the set of W modelled cross-section values v1 . . . vW is described by a parametrized function with R parameters. In an example, the number of parameters is smaller than the number N of measured cross-section values, with R<N. The R parameters are then derived for example by least square optimization of the set of W modelled cross-section values v1 . . . vW to the set of measured cross-section values v1 . . . vN.

In an example, the model comprises a first set of P parameters A1, . . . AP of a first parameter model S(A1, . . . AP) and a second set of Q parameters B1, . . . BQ of a second parameter model T(B1 . . . . BQ). The first parameter model S represents a shift error of the lateral positions of the cross-section values of the second group of structures of presumably known depth in each of the image slice. The second parameter model T represents the lateral position error of the cross-section values of the second group of structures of presumably known depth in one cross-section image slice according to a local error in or of the milling angle GF of a cross-section surface.

The actual parameters A and B are then derived for example by least square optimization to the set of measured cross-section values v1 . . . vN.

In step S6, from the first set of W modelled cross-section values v1 . . . vW of the group of structures of presumably known depth, a depth map Zᵢ(x,y) is computed for each of the plurality of image slices. With the plurality of depth maps Zᵢ(x,y) and the plurality of cross-section image slices, a 3D volume image data set of high accuracy is generated. In step S7, finally the parameters or features of interest of 3D semiconductor structures in the inspection volume are derived. For example, the semiconductor structures of interest are formed by a plurality of repetitive semiconductor structures, such as the HAR structures shown in FIG. 2. The parameters or features of interest of the plurality of repetitive semiconductor structures can for example be a volume, a lateral position, a dimension such as a distance or diameter, an overlay area, an average value of these features, and a maximum deviation from an average value of an individual structure. The parameters or features of interest are finally attributed to the inspection site and stored in the memory of the control unit 2 or written to an inspection file.

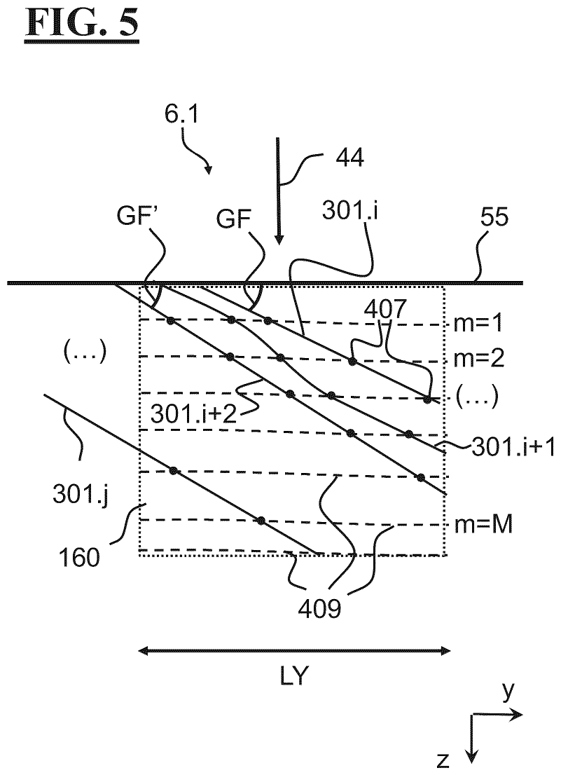

The method according to the second embodiment is described in more detail at the example of FIG. 5. The inspection site 6.1 with the inspection volume 160 is aligned under the charged particle imaging system for imaging during use with the imaging charged particle beam 44. A plurality of J cross-section surfaces 301.1, 301.2 to 301.J is determined by their milling position y1 to yJ and their milling angle GF. Under control of the control unit 19, the cross-section surfaces 301.1, 301.2 to 301.J are then milled sequentially into the inspection volume 160, and after each milling of a surface with the FIB beam (not shown), a corresponding cross-section image slice is obtained by the imaging charged particle beam 44. The plurality of layer structures 409 such as word lines described above with a number of M layers with index m=1, 2, . . . M is intersected by a plurality of J cross-section surfaces 301.i (with i=1 . . . J). Each of the 2D cross-section image slices comprise several cross-section images 407 of the layers or metal lines 409. The cross-section images 407 visible in the cross-section surfaces 301.1, 301.2 to 301.J are indicated by filled dots, some indicated with label 407. Each cross-section image slice is obtained by scanning of the imaging charged particle beam 44, and each image slice comprises at least some cross sections of the second group of structures of presumably known depth, arranged in a plurality of M layers parallel to a surface of the semiconductor wafer. The total number of cross-section images of metal lines is N. From the N cross-section images 407, N cross-section values v1 . . . vN are determined.

The layers 409 are typically parallel to the surface 55 but can show some slowly varying deviation to the surface 55. The cross-section surfaces 301 can show deviations from predetermined milling angles GF, as illustrated at the examples of cross sections surfaces 301.i with angle GF and 301.i+2 with a slightly different slanted angle GF′ with respect to the surface 55. Furthermore, the cross-section surfaces can show a waviness, as illustrated at cross-section 301.i+1. The effect is highly exaggerated in FIG. 5. These errors of the layers 409, and the errors from the milling process are considered in the parameter model, for example by separated error contributions S and T described below in more detail. Thereby it is assumed that the errors typically are only slowly varying functions from slice to slice of from layer to layer 409.

According to an example, the model edge positions Y of each cross-section image slice of index i can be described by the functional dependency of approximately M*J equations:

$${Y}_{i}^{m} = {Y}_{i = 1}^{m} + {Y}_{shift} ( i ) + α ( i ) \cdot ( {Y}_{i = 1}^{m} - {Y}_{i = 1}^{m = 1} ) , \qquad ( 1 )$$

Yshift (i) is a term characterizing the shift of the ith cross section surface in Y-direction corresponding to the milling distance d.

α(i) is a scaling term which characterizes the change in the averaged slope of the cross-section surface. Ideally, the difference of edge positions Y in an image slice directly relates to the difference of the depth or z-position between the mth layer and the first layer with m=1 and the milling angle GF

$$( {Y}_{1}^{m} - {Y}_{1}^{1} ) = ( {Z}^{m} - {Z}^{1} ) / tan ( G F ) \qquad ( 2 )$$

α(i) thus describes a variation to this ideal relation.

According step S5, the functions Yshift (i) and a (i) from Eq. (1) are described by parameter models S and T with a finite number of parameters S=Yshift (i)=Yshift (A1, A2, AP; i), and T=α(i)=α(B1, B2, BQ; i), where P and Q are the corresponding numbers of parameters. Parameter models S and T can for example by polynomials of low order or B-splines.

The system of model equations (1) can thus be written as follows:

$${Y}_{i}^{m} = f ( {Y}_{1}^{1} , {Y}_{1}^{2} , … , {Y}_{1}^{M} , {A}_{1} , {A}_{2} , … , {A}_{P} , {B}_{1} , {B}_{2} , … , {B}_{Q} , i , m ) \qquad ( 3 )$$

After extracting and measuring the first set of measured cross-section values v1 . . . vN of the structures of presumably known depth according to Step S4, a first set of N measured cross-section values v1 . . . vN is determined. The N measured cross-section values are corresponding in this example to the edge positions Yₙ. With the measured cross-section values Yₙ, equation (5) can be solved for example by least square optimization and the model edge positions Y can be determined within each image slice at every position. The equation system can be solved as long as the number N exceeds the number of parameters L+P+Q with N>=L+P+Q. Even with a lower number N, a best fit approximation can be obtained, for example by using a priori information.

From the model edge positions according equation (5) with the optimized parameters A and B, the depth maps Zᵢ(x,y) for each of the image slices can be computed and the 3D volume image is obtained with high accuracy and robustness.

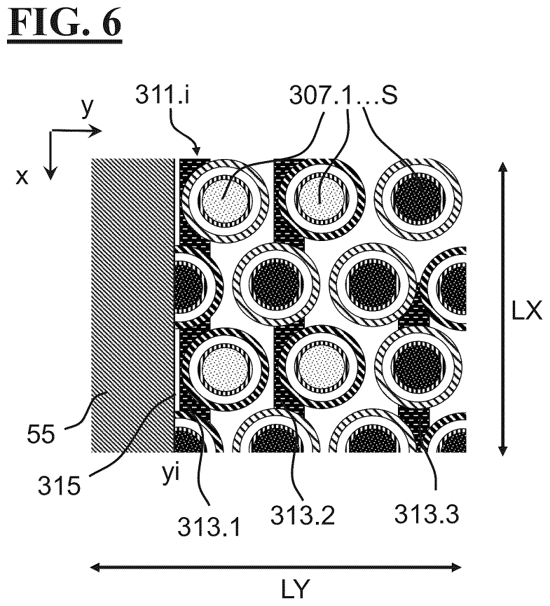

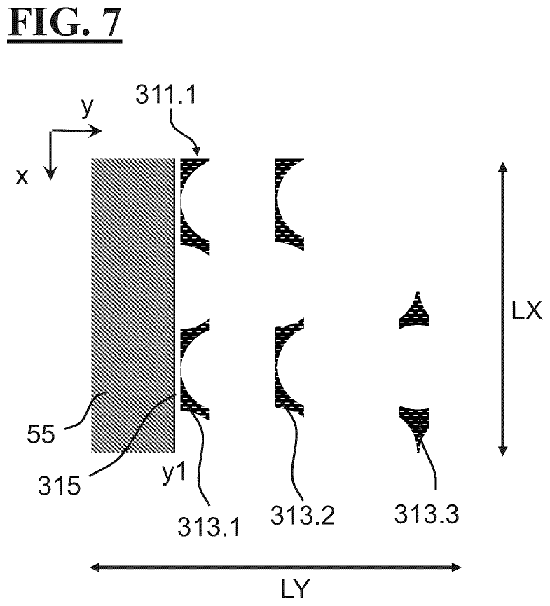

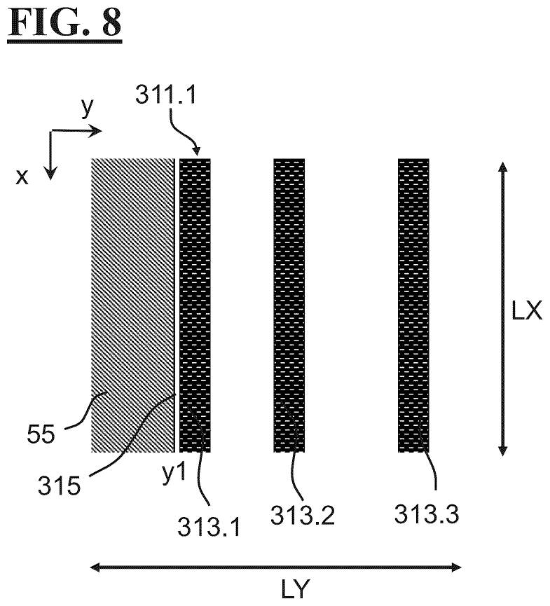

FIG. 6 shows a cross-section image slice 311.i generated by the imaging charged particle beam 44 and corresponding to the ith cross-section surface 301.i. The cross-section image slice 311.i comprises an edge line 315 between the slanted cross-section and the surface 55 of the wafer at the edge coordinate yi. Right to the edge, the image slice 311.i shows several cross-sections 307.1 . . . 307.S through HAR structures which are intersected by the cross-section surface 301.i. In addition, the image slice 311.i comprises cross sections 313.1 to 313.3 of several word lines at different depths or z-positions. With these cross sections of word lines 313.1 to 313.3, a depth map Z₁(x,y) of the slanted cross-section surface 301.i is generated. FIG. 7 illustrates an example of the cross-section image slice 311.i where the cross-sections 307.1 . . . 307.S through HAR structures are removed, for example by image processing. From this example it can be seen that not all cross sections of word lines 313 can be detected with the same precision and not all word lines extend through the full image slice. In many examples, the material of the metal lines provides in addition a lower imaging contrast. In addition, the edges or contours of the metal lines in the cross-section images might not be identified unambiguously with the desired precision of for example below 1 nm. Therefore, the first set of cross-section values cannot always be detected by an automated image processing in the plurality of cross-section image slices with a number sufficient enough to compute the depths maps directly from the set of measured cross-section values v1 . . . vN and the method according to the second embodiment including step S5 can be used. FIG. 8 illustrates a result of a model cross-section image obtained from the model function according to equation (3) with the optimized set of parameters A and B. As illustrated by this example, missing cross-section image details of metal lines are here interpolated by the modelled cross-section values v1 . . . vW of the word lines, here corresponding to the second group of structures of presumably known depth. Furthermore, the impact of random measurement artefacts in the determination of the measured cross-section values u1 . . . uN is reduced, for example by a proper selection of the polynomials S and T comprising only low order terms. The method according to the disclosure is thus robust against measurement artefacts, even when the imaging conditions offer only low contrast for the structures of presumably known depth.

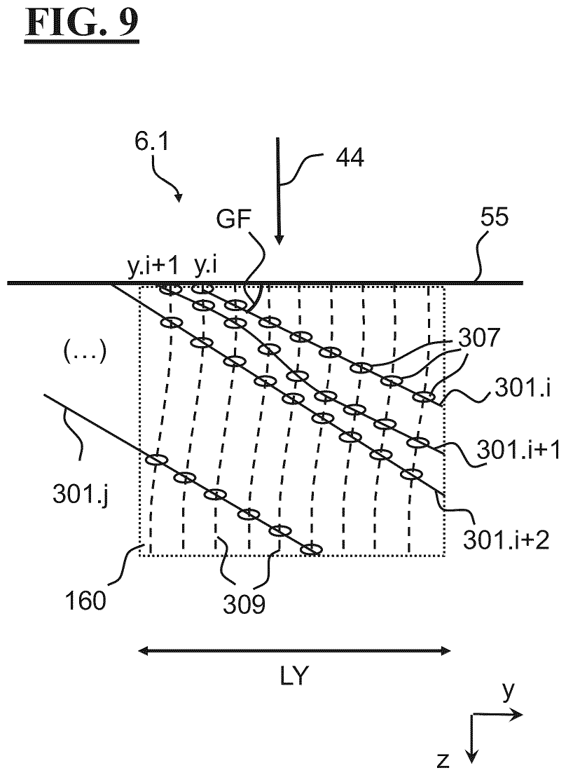

The 3D volume image data set obtained in step S6 from the plurality of cross-section image slices, with image pixels of known lateral position, and the depth maps Z (x,y), one for each cross-section image slice, such that in addition the z-position for each image pixel is known. The pixel data from the many image pixels can be transformed in a regular 3D raster. From the 3D volume image, whether in a regular 3D raster or not, properties of the structures of interest in the inspection volume can be computed with high accuracy and high robustness. Such structures of interest are typically given by a group of repetitive 3D structures, such as high aspect ratio (HAR)-structures of memory devices. FIG. 9 illustrates a plurality of such HAR structures 309 inside an inspection volume 160. The plurality if HAR structures 309 are intersected by the plurality of cross-section surfaces 301.i to 301.j described above, and a plurality of cross-section images 307 of HAR structures are obtained. With the depth maps Zᵢ(x,y) determined according to the method steps S5 and S6, each position of a cross-section 307 in the 3D volume is determined with high precision, including the depth. From the 3D volume image, properties of the HAR structures can be obtained with high accuracy. Properties can be edge positions, center position, a radius, a diameter, an eccentricity, a cross-section area, a distance, an overlay error, or any statistical evaluation to such properties, like an average or a deviation such as a roughness.

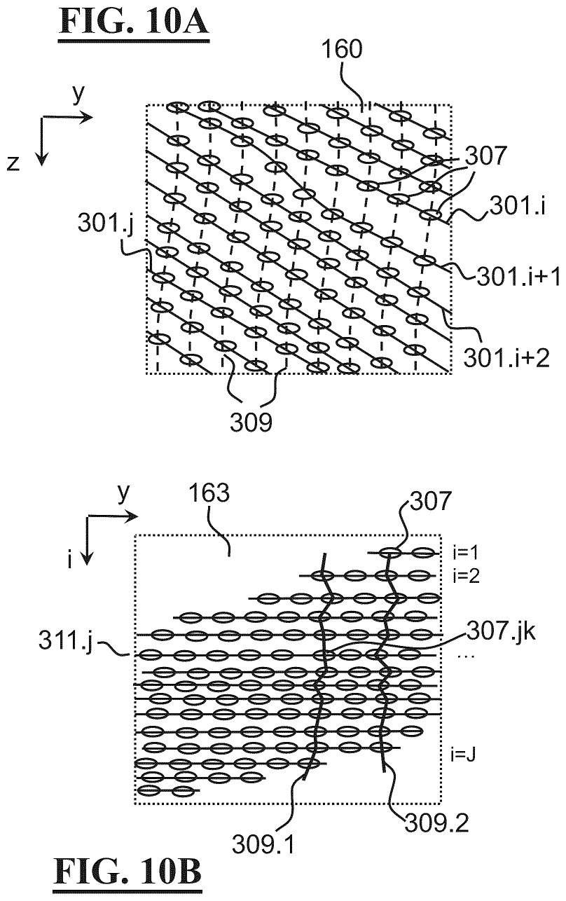

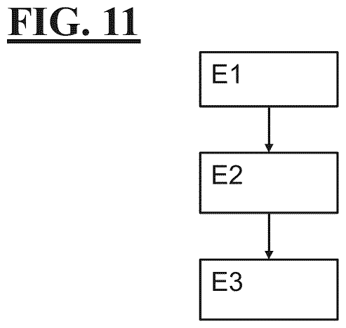

With the second embodiment of the disclosure, a robust method for the generation a 3D volume images is given, which is insensitive to errors during the milling and imaging process and which enables a wafer inspection without destruction of the wafer. The method can be desirable when the structures of known depth cannot be obtained by the charged particle imaging conditions as desired for a direct determination of the Z-maps of cross-section image slices. In a third embodiment, a method of the generation of a 3D volume image is provided. FIGS. 10A-10B illustrate an example of HAR memory channels in a 3D-memory stack. FIG. 10A shows the plurality of cross sections 301.1 to 301.J at a slanted angle GF through an inspection volume 160 with a plurality of HAR structures 309. Each cross-section surface intersects a plurality of HAR structures with cross sections 307. FIG. 10B shows the cross-section image data stack with plurality of cross-section images 311.1 to 311.J. The cross sections 307.jk of the HAR structures are detected and attributed to an individual HAR structure and the centroid of each cross-section is determined. The centroids form approximate trajectories of the HAR structures through the data stack 163. Each cross-section image, which is for example aligned after a first alignment at fiducials or alignment marks (not shown) or by a precision stage, still shows a lateral displacement due to drifts and other effects of the milling or imaging with the dual beam system or charging effects of the wafer. Furthermore, the cross-section surfaces 301 can show a waviness (see for example cross-section surface 301.i+1 in FIG. 10A). These effects lead—even after the initial alignment based on the alignment marks or with the monitoring of the stage position with high precision—to the fluctuating centroid lines 309.1 or 309.2 as illustrated in FIG. 10B. The residual misalignment comprises an average difference from image slice to image slice. According to the method of the third embodiment, it is assumed that the residual misalignment of the slices consists solely of specific contributions within a selected frequency range. The method is illustrated in FIG. 11.

In a first step E1, the lateral position of each cross-section of an HAR centroid trajectory with index n perpendicular to the surface 55 of the wafer is described for each image slice 311.j by

$$\{ \begin{matrix}{x}_{j}^{n} = {x}_{ref}^{n} + {dx}_{j}^{n} , \\ {y}_{j}^{n} = {y}_{ref}^{n} + {dy}_{j}^{n}\end{matrix} \qquad ( 4 )$$

with a lateral displacement dxⱼⁿ, dyⱼⁿ and with reference position x_{ref}, y_{ref} of each of the cross-section of index n=1 . . . J. The reference positions x_{ref}, y_{ref} can for example be the positions of the centroids in an arbitrary reference cross-section image slice.

In a second step C2, the centroid trajectories are analyzed, and a filtering is applied to the lateral displacement dxⱼⁿ, dyⱼⁿ. In an example, the high frequency part of the displacements dxⱼⁿ, dyⱼⁿ from slice to slice is subtracted. This is for example achieved by computing the average lateral displacement Axⱼ=Averageⱼ(dxⱼⁿ;n), Ayⱼ=Averageⱼ(dyⱼⁿ;n) of the cross-section of the HAR structures in each cross-section image slice. It is then assumed that high frequency changes of the average lateral displacement Axⱼ, Ayⱼ are artefacts from the measurement.

In a further example of step E2, the filtering is obtained by fitting a parameter model S2 (C1, C2, . . . ; i) to the average lateral displacement Axⱼ, Ayⱼ of the cross-section centroids with respect to reference positions x_{ref}, y_{ref} with i=1 . . . . J for the image slices. The parameters of the parameter model represent the real displacements of the centroids of the HAR structures, while high frequency contributions are filtered out by the least square fitting to the parameter model. The parameters C1, C2, . . . can for example describe a linear tilt, a curvature, or a low frequency harmonic function.

The parameter model S2(C1, C2, . . . ; i) of the average lateral displacement Axⱼ, Ayⱼ of the cross-section centroids can be complementary to the parameter model S(A1, A2, . . . AP; i) of the lateral shift of the structures of presumably known depth according to the second embodiment.

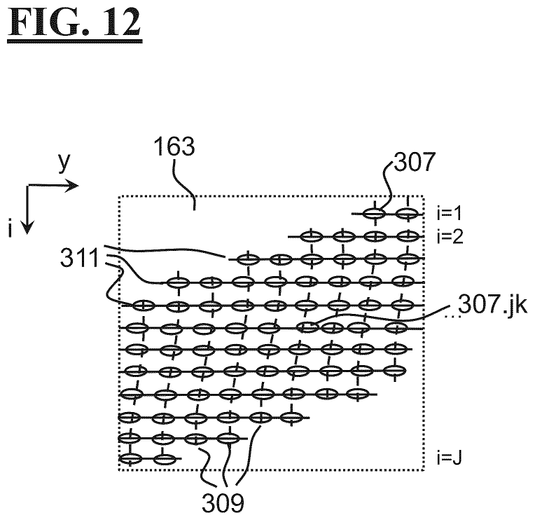

In step E3, cross section mage slices are re-aligned according to the low frequency part of the average lateral displacement Axⱼ, Ayⱼ. The high frequency part of the average lateral displacement Axⱼ, Ayⱼ, is subtracted and HAR channel trajectories 309 with only low frequency deviations from slice to slice are obtained. A result is illustrated in FIG. 12. Since only an average displacement vector per image slice is filtered, local displacements within an image slice such as of cross-section 307.jk are preserved in the image data stack. FIG. 12 shows the result of the lateral alignment of the image slices 311.1 to 311.J after removal of the average high frequency displacements from image slice to image slice. The low spatial frequency trends of the HAR structures such as their common tilt or curvature (wiggling) reflect the real properties of the structures.

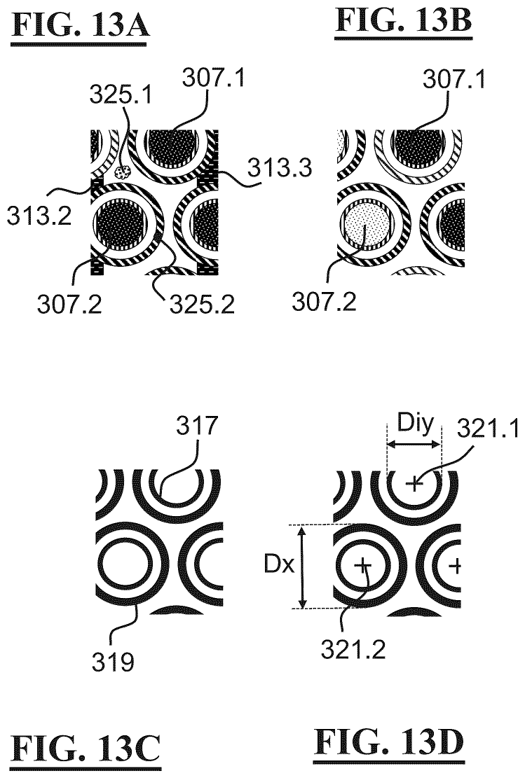

FIGS. 13A-13D illustrate a simplified example of extracting the centroid positions from the plurality of cross sections. FIG. 13A shows a segment of the cross-section image slice 311.1, comprising cross-sections 307.1 and 307.2 of HAR structures and cross sections of word lines 313.2 and 313.3. The cross-section image slice 311.1 can further comprise some defects or imaging artefacts 325.1 and 325.2. In a first step, the image is cleaned and the cross sections of word lines 313.2 and 313.3 are removed by filtering techniques, for example a threshold filtering or an erosion process. The filtering can also be performed by feature or pattern recognition methods known in the art, for example by edge detection, Fourier filter or correlation techniques including machine learning methods. The result of the cleaned image is shown in FIG. 13B. The cross sections 307.1 and 307.2 of the HAR structures are then approximated to models of the cross sections, for example by two circular rings 317 and 319 (FIG. 13C). From these rings, parameters such as for example the diameter Dx of the outer rings 319, the diameter Diy of the inner ring 317, or the center positions 321.1 and 321.2 can be determined within the cross-section image slices (FIG. 13D). This process is repeated for the series of J cross-section image slices.

The subject matter of the disclosure includes the following clauses:
Clause 1. A method of generating a 3D volume image of an inspection volume in a semiconductor wafer, comprising
a) obtaining a plurality of J cross section image slices by iteratively and subsequently milling and imaging a plurality of cross section surfaces at a slanted angle GF through the inspection volume;
b) determining a set of N measured cross section values u1 . . . uN of a group of structures of presumably known depth from the plurality of J cross section image slices;
c) determining, from the set of N measured cross section values u1 . . . uN, a set of W modelled cross-section values v1 . . . vW of the group of structures of presumably known depth;
d) determining, from the set of W modelled cross-section values v1 . . . vW, for each of the cross section image slices, a depth map Zj(x,y);
e) determining a 3D volume image from the plurality of J cross section image slices and the depth maps Zj(x,y).
Clause 2. The method according to clause 1, wherein each of the cross-section values represent an edge position or a center position of one of the structures of presumably known depth.
Clause 3. The method according to clause 1 or 2, wherein the set of W modelled cross-section values v1 . . . vW is described by a parameter model having a number of R<N parameters.
Clause 4. The method according to clause 3, wherein the R parameters of the set of W modelled cross-section values v1 . . . vW are determined from the set of measured cross-section values v1 . . . vN by least square optimization.
Clause 5. The method according to any of the clauses 3 or 4, wherein the set of W modelled cross-section values v1 . . . vW is described by the addition of a first parameter model S representing a shift error of the lateral positions of the cross-section values of the group of structures of presumably known depth in each of the image slices, and a second parameter model T according to a local error of the milling angle GF of a cross section surface.
Clause 6. The method according to any of the clauses 1 to 5, wherein the group of structures of presumably known depth comprise structures in a plurality of M layers parallel to a surface of the semiconductor wafer.
Clause 7. The method according to any of the clauses 1 to 6, further comprising the steps of determining at least a second set of measured cross section values of a group of repetitive three-dimensional structures in the plurality of J cross section image slices and determining a property of the group of repetitive three-dimensional structures.
Clause 8. The method according to clause 7, wherein the second set of measured cross section values represent center positions of cross sections of the group of repetitive three-dimensional structures.
Clause 9. The method according to clause 8, further comprising the steps of determining a plurality of lateral displacements of the center positions from reference center positions, and determining an average lateral displacement by averaging the plurality of lateral displacements for each cross-section image slice, and filtering a high frequency part of the average displacement from cross-section image slice to cross section image slice.
Clause 10. The method according to any of the clauses 1 to 9, wherein the number J of cross section image slices is J>200, J>1000, or J>5000.
Clause 11. An inspection system for generating a 3D volume image of an inspection volume in a semiconductor wafer, comprising
   a wafer support on a wafer stage for receiving a wafer;
   a dual beam system with a focus ion beam (FIB) arranged at a slanted angle GF with respect a surface of the wafer support and an imaging charged particle beam system arranged at an angle approximately perpendicular to the surface of the wafer support;
   a control unit with a memory and a processor for executing during use instructions to perform any of the method steps according to clauses 1 to 10.
Clause 12. The inspection system according to clause 11, further comprising
   a precision interferometer for controlling a position of the wafer stage, and
   a housing and a control configured for controlling a vacuum condition within the housing, wherein the precision interferometer and the wafer stage are arranged within the housing.

The disclosure described by examples and embodiments is however not limited to the clauses but can be implemented by those skilled in the art by various combinations or modifications thereof.

### A LIST OF REFERENCE NUMBERS IS PROVIDED

1 Dual Beam Device
2 Operation Control Unit
4 first cross section image features
6 measurement sites
8 wafer
12 Vacuum Compartment
15 wafer support table
16 stage control unit
17 Secondary Electron detector
19 Control Unit
21 Position sensor
40 charged particle beam (CPB) imaging system
42 Optical Axis of imaging system
43 Intersection point
44 Imaging charged particle beam
48 Fib Optical Axis
50 FIB column
51 focused ion beam
52 cross section surface
53 cross section surface
55 wafer top surface
73 second cross section image feature
77 cross section image segments of HAR channels
78 vertical edge of a HAR structure
80 horizonal edge of a layer
155 wafer stage
160 inspection volume
163 image data stack
301 cross section surface
307 measured cross section image of HAR structure
309 HAR structures
311 cross section image slice
313 cross sections through word lines
315 edge with surface
317 inner circular ring
319 outer circular ring
321 center position
325 defects or artefacts
407 cross sections of structures of presumably known depth
409 plurality of layers

What is claimed is:

1. A method, comprising:
obtaining a plurality of cross section image slices of an inspection volume in a semiconductor wafer by iteratively and subsequently milling and imaging a plurality of cross section surfaces at a slanted angle through the inspection volume;
determining a set of measured cross section values of a group of structures of presumably known depth from the plurality of cross section image slices;
from the set of measured cross section values, determining a set of modelled cross-section values of the group of structures of presumably known depth;
for each cross section image slice, determining a depth map from the set of modelled cross-section values, thereby providing a plurality of depth maps; and
determining a 3D volume image from the plurality of cross section image slices and the plurality of depth maps.

2. The method of claim 1, wherein each cross-section value represents an edge position of one of the structures of presumably known depth.

3. The method of claim 1, wherein each cross-section value represents a center position of one of the structures of presumably known depth.

4. The method of claim 1, wherein the set of modelled cross-section values is described by a parameter model having a number of parameters that is less than a number of measured cross section values in the set of measured cross section values.

5. The method of claim 4, further comprising using least square optimization to determine the parameters of the set of modelled cross-section values from the set of measured cross-section values.

6. The method of claim 5, wherein the set of modelled cross-section values is described by adding: i) a first parameter model representing a shift error of lateral positions of the cross-section values of the group of structures of presumably known depth in each image slice; and ii) a second parameter model according to a local error of the milling angle of a cross section surface.

7. The method of claim 4, wherein the set of modelled cross-section values is described by adding: i) a first parameter model representing a shift error of lateral positions of the cross-section values of the group of structures of presumably known depth in each image slice; and ii) a second parameter model according to a local error of the milling angle of a cross section surface.

8. The method of claim 4, wherein each cross-section value represents an edge position of one of the structures of presumably known depth, or each cross-section value represents a center position of one of the structures of presumably known depth.

9. The method of claim 1, wherein the group of structures of presumably known depth comprises structures in a plurality of layers in the inspection volume parallel to a surface of the semiconductor wafer.

10. The method of claim 9, wherein each cross-section value represents an edge position of one of the structures of presumably known depth, or each cross-section value represents a center position of one of the structures of presumably known depth.

11. The method of claim 9, wherein the set of modelled cross-section values is described by a parameter model having a number of parameters that is less than a number of measured cross section values in the set of measured cross section values.

12. The method of claim 1, further comprising:
determining a second set of measured cross section values of a group of repetitive three-dimensional structures in the plurality of cross section image slices; and
determining a property of the group of repetitive three-dimensional structures.

13. The method of claim 12, wherein the second set of measured cross section values represents center positions of cross sections of the group of repetitive three-dimensional structures.

14. The method of claim 13, further comprising:
determining a plurality of lateral displacements of the center positions from reference center positions;
determining an average lateral displacement by averaging the plurality of lateral displacements for each cross-section image slice; and
filtering a high frequency part of the average lateral displacement from cross-section image slice to cross section image slice.

15. The method of claim 14, wherein each cross-section value represents an edge position of one of the structures of presumably known depth, or each cross-section value represents a center position of one of the structures of presumably known depth.

16. The method of claim 14, wherein the set of modelled cross-section values is described by a parameter model having a number of parameters that is less than a number of measured cross section values in the set of measured cross section values.

17. The method of claim 1, wherein the number of cross section image slices is at least 200.

18. One or more machine-readable hardware storage devices comprising instructions that are executable by one or more processing devices to perform operations comprising the method of claim 1.

19. A system, comprising:
one or more processing devices; and
one or more machine-readable hardware storage devices comprising instructions that are executable by the one or more processing devices to perform operations comprising the method of claim 1.

20. The system of claim 19, further comprising:
a stage configured to hold a semiconductor wafer;
a focused ion beam;
an imaging charged particle beam system;
an interferometer; and
a housing,
wherein the stage, the focused ion beam, the imaging charged particle beam system, the interferometer and the stage are within the housing.
